(19) United States
(12) Patent Application Publication
(10) Pub. No.: US 2009/0002028 A1
(43) Pub. Date: Jan. 1, 2009

(54) MIXED-VOLTAGE I/O BUFFER TO LIMIT HOT-CARRIER DEGRADATION

(75) Inventors: Ming-Dou Ker, Hsinchu (TW); Hui-Wen Tsai, Kaohsiung City (TW); Ryan Hsin-Chin Jiang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMAZING MICROELECTRONIC CORPORATION, Taipei County (TW)

(21) Appl. No.: 11/769,716

(22) Filed: Jun. 28, 2007

(51) Int. Cl. H03K 19/0175

(52) U.S. Cl. 326/80

(57) ABSTRACT

A Mixed-voltage input and output (I/O) buffer including a pre-driver unit, a bulk-voltage generating unit, a first to a third transistors and an input stage unit is provided. The pre-driver unit outputs a first source/drain and a second signal. The bulk-voltage generating unit determines whether a first voltage or a pad voltage is used as a bulk voltage according to the pad voltage level. A gate of the first transistor receives the first signal, and a bulk, a first source/drain and a second source/drain of the first transistor are respectively coupled to the bulk voltage, the first voltage and the pad. A gate of the third transistor receives the second signal, and a first source/drain and a second source/drain of the third transistor are respectively coupled to the input stage unit for receiving an input signal from the pad and a second voltage.

### BACKGROUND OF THE INVENTION

1. Field of the Invention

The present invention generally relates to an input and output (I/O) buffer, and more particularly, to a mixed-voltage I/O buffer that can limit hot-carrier degradation.

2. Description of Related Art

With the rapid development of complementary metal oxide semiconductor techniques, the dimension of a transistor continues to decrease so as to reduce chip area and fabrication cost and increase operating speed and power performance. However, the source voltage needed to drive the chip also decreases correspondingly. If a voltage higher than the source voltage is used in a signal transmission process, then two different voltage levels coexist when the chip operates so that the higher voltage can overstress the chip.

Because the chip is designed using transistors with a small dimension, a number of problems will arise when the chip is overstressed, for example, gate-oxide reliability may be lowered, hot-carrier degradation may intensify and unwanted leakage current paths may be generated. To resolve these problems, an input and output (I/O) buffer for the chip capable of adapting to mixed voltages must be designed.

FIG. 1 is a circuit diagram of a conventional I/O buffer. As shown in FIG. 1, the power supply voltage is assumed to be a system voltage VDD. The I/O buffer 100 includes a pre-driver 101, transistors P0 and N0, and an input buffer 103. The transistor P0 is a P-type transistor and the transistor N0 is an N-type transistor. When the I/O buffer 100 is in an input mode, the pre-driver 101 outputs a logic high (for example: the system voltage VDD) control signal PU and a logic low (for example: a ground voltage GND) control signal PD to a gate of the transistor P0 and the transistor N0, respectively, so as to make both transistors P0 and N0 non-conductive. Therefore, the input signal from the pad 102 can be transmitted into the interior of an integrated circuit through the input buffer 103 via a node Din.

However, when an input signal having a high voltage level (for example: 2×VDD) is input via the pad 102, the PN junction diode formed between the drain and the bulk of the transistor P0 is forward bias and the transistor P0 is also conductive. Therefore, the PN junction diode and the conductive transistor P0 form an additional leakage current path.

In addition, the voltage between the gate and the drain of the transistor N0 and the voltage between the drain and the source of the input buffer will both exceed the normal operating voltage level. Therefore, the transistor N0 and the transistor inside the input buffer 103 may have gate-oxide reliability problem, and the excess voltage between the drain and the source of the transistor N0 may lead to hot-carrier degradation problem.

In an article with the title “Overview and Design of Mixed-Voltage I/O buffer With Low-Voltage Thin-Oxide CMOS Transistor” IEEE Trans. on Circuits and Systems I. Regular Paper, Vol. 53 no. 9, 2006, a few techniques have been proposed to resolve the foregoing problems. FIG. 2 is a circuit diagram of another conventional I/O buffer. As shown in FIG. 2, the I/O buffer includes a pre-driver 201, transistors MP0, MN0˜MN1, an input buffer circuit 203, a gate-tracking circuit 204 and a dynamic N-well bias circuit 205. The transistor MP0 is a P-type transistor and the transistors MN0˜MN1 are N-type transistors.

The I/O buffer 200 uses a stacked N-type transistor technique. In other words, the transistors MN0 and MN1 are used to increase the gate-oxide reliability of the transistor MN1 and the transistors inside the I/O buffer 200. A gate of the transistor MN0 is coupled to the system voltage VDD. Therefore, when a high voltage (for example: 2×VDD) input signal is input via the pad 202, the voltage at the drain (node A) of the transistor MN1 can be reduced so as to prevent the gate oxide layers of the transistor MN1 and the transistors inside the I/O buffer circuit 203 from being overstressed.

To resolve the problem of turning on the transistor MP0 and forming a leakage current path by the application of a high voltage input signal, the I/O buffer 200 utilizes a gate-tracking circuit 204 to control the gate voltage of the transistor MP0. When a high voltage (for example: 2×VDD) input signal is input via the pad 202, the gate-tracking circuit 204 increases the gate voltage of the P-type transistor MP0 to the voltage level of the input signal so as to make the P-type transistor MP0 non-conductive.

Furthermore, the gate-tracking circuit 204 also uses the stacked N-type transistor technique. In other words, the transistors MN3˜MN4 are used to increase gate-oxide reliability, and the I/O buffer 200 also uses the transistor MP1 to limit the gate voltage of the transistors inside the buffer INV1.

In addition, the I/O buffer 200 uses a dynamic N-well bias circuit 205 to control the bulk voltage of the transistor MP0, that is, the N-well voltage. When a high voltage (for example: 2×VDD) input signal is input via the pad 202, the dynamic N-well bias circuit 205 increases the bulk voltage of the transistor MP0 to the voltage level of the input signal. Therefore, the PN junction diode inside the transistor MP0 forming a leakage current path due to forward bias can be prevented.

However, when the I/O buffer 200 makes a transition from receiving a high voltage (for example: 2×VDD) input signal to transmitting a low logic level (for example: 0V) output signal, the stacked transistors MN0 and MN3 used by the I/O buffer 200 can be affected by hot-carrier degradation problem.

Here, it should be noted that the control signals OE and PD are at logic low levels when the I/O buffer 200 is in an input mode (for receiving an input signal) so as to make both transistors MN4 and MN1 non-conductive. When the I/O buffer 200 is in an output mode (for transmitting an output signal), the control signal OE is at a high logic level and the control signals PD and PU change according to the input signal Dout. Therefore, in the foregoing transition state, the control signals OE and PD will suddenly change from a logic low level (for example: 0V) to a logic high level (for example: VDD).

When the source voltages (node A, B) of the transistors MN0 and MN3 suddenly drop following the changes of the control signals OE and PD to a high logic level, the drain voltages of the transistors MN0 and MN3 are maintained at the original voltage level or lowered slowly due to body effect and parasitic effect. Consequently, the voltages between the drain and the source of the transistors MN0 and MN3 will increase and exceed the nominal supply voltage, thereby causing the hot-carrier degradation problem. Furthermore, the drain (or source) of the transistor MP5 is coupled to the drain of the transistor MN0 and the gate of the transistor MP5 is coupled to the source of the transistor MN0. Since the transistor MN0 suffered hot-carrier degradation problem, the gate-oxide reliability of the transistor MP5 may also be reduced.

In addition, when the I/O buffer 200 makes a transition from receiving a high voltage (for example: 2×VDD) input signal to transmitting a high logic level (for example: VDD) output signal, the transistors MN2˜MN3 and MP2 can be affected by hot-carrier degradation problem. In this transition state, the control signal PU will suddenly change from a high logic level (for example: VDD) to a logic low level (for example: 0V) while the control signal OE will suddenly change from a low logic level (for example: 0V) to a high logic level (for example: VDD).

When the drain voltages (node C) of the transistors MN2 and MP2 drop suddenly following the changes of the control signal PU to a logic low level, the source voltages (node D) of the transistors MN2 and MP2 are still maintained at the high voltage level of the input signal or reduced slowly. Therefore, a large voltage between the drain and the source of the transistors MN2 and MP2 is produced and hence may lead to the hot-carrier degradation problem.

Furthermore, in an article with the title “5.5V I/O in a 2.5V 0.25-μm CMOS Technology” IEEE J. Solid-State Circuits, vol. 36, no. 3, pp. 528-538, March 2001, a circuit design for controlling the gate of a stacked N-type transistor so as to resolve the low gate-oxide reliability and hot-carrier degradation problems is proposed. FIG. 3 is a circuit diagram of yet another conventional I/O buffer. As shown in FIGS. 2 and 3, the main difference between the I/O buffer 300 and the I/O buffer 200 is that the circuits 306a and 306b described in the article are respectively used in the stacked N-type transistors of the I/O buffer 200 (that is, the transistors MN0˜MN1 and the transistor MN3˜MN4 in FIG. 2).

In the circuit 306a, transistors MPT0˜MPT1 control the gate voltage of a transistor MN5. In the circuit 306b, transistors MPT2˜MPT3 control the gate voltage of a transistor MN6. When the I/O buffer 300 receives a high voltage (for example: 2×VDD) input signal, a bias voltage 2×VDD is applied to the gates of the transistors MN5 and MN6 through the transistors MPT1 and MPT3, respectively. Furthermore, because the transistors MN5 and MN6 have a diode connectivity (that is, the gate and the drain are coupled together), the source voltages (node E and F, respectively) of the transistors MN5 and MN6 are controlled to (2×VDD−ΔV). Conversely, regardless of whether the I/O buffer 300 is in an input mode (for receiving an input signal) or an output mode (for transmitting an output signal), the gate voltages of the transistors MN5 and MN6 are at a high logic level (for example: VDD) when the signal of the pad 302 is at a logic low level (for example: 0V).

When the I/O buffer 300 makes a transition from receiving a high voltage (for example: 2×VDD) to transmitting a low voltage (for example: 0V) output signal, the initial source voltages (node E and F) of the transistors MN5 and MN6 are (2×VDD−ΔV). At this time, the transistors MN1 and MN4 conduct as a result of the changes of the control signals OE and PD to a high logic level and pull down the source voltages (node A and B) of the transistors MN0 and MN3. Therefore, the voltage between the drain and the source of the transistors MN0 and MN3 inside the I/O buffer 300 is smaller than that of the I/O buffer 200 in FIG. 2, and their difference is ΔV.

In addition, the conductive transistors MN5 and MN6 operate close to a linear saturated region, that is, the current Ids through the transistors MN5 and MN6 is relatively large. Therefore, the drain voltages (node E and F) of the transistors MN1 and MN3 can be effectively reduced. However, when the I/O buffer 300 makes a transition from receiving a high voltage (for example: 2×VDD) to transmitting a low voltage (for example: VDD) output signal, this circuit design has no means of lowering the excess voltage between the drain (node C) and the source (node D) of the transistors MN2 and MP2. Consequently, the hot-carrier degradation problem still persists.

### SUMMARY OF THE INVENTION

Accordingly, the present invention is directed to an Mixed-voltage input and output (I/O) buffer. The Mixed-voltage I/O buffer has a high/low voltage tolerance characteristic, and regardless of whether the Mixed-voltage I/O buffer is in a stable state or in a transient state, this Mixed-voltage I/O buffer has the advantages of increasing the gate-oxide reliability of its internal transistors and preventing its internal transistors from subjecting to the hot-carrier degradation effect.

According to an embodiment of the present invention, an Mixed-voltage input and output (I/O) buffer is provided. The Mixed-voltage I/O buffer includes a pre-driver unit, a bulk-voltage generating unit, first to third transistors and an input stage unit. The pre-driver unit outputs a first and a second signal. The bulk-voltage generating unit determines whether a first voltage (e.g. a system voltage VDD) or a pad voltage is connected to the output to be used as a bulk voltage according to the pad voltage level. A gate of the first transistor receives the first signal, and a bulk, a first source/drain and a second source/drain of the first transistor are respectively coupled to the bulk voltage, the first voltage and the pad. A gate, a first source/drain and a second source/drain of the second transistor are respectively coupled to the bulk voltage, the second source/drain of the first transistor and a first source/drain of the third transistor. A gate of the third transistor receives the second signal, and a second source/drain of the third transistor is coupled to a second voltage. The input stage unit is coupled to the first source/drain of the third transistor for receiving an input signal from the pad.

In an embodiment of the present invention, the foregoing I/O buffer further includes a gate-tracking unit. The gate-tracking unit is coupled between the gate of the first transistor and the pre-driver unit. If the pad voltage is greater than the first signal, then the pad voltage is selected and output to the gate of the first transistor. Otherwise, the first signal is selected and output to the gate of the first transistor.

The present invention uses the bulk voltage provided by the bulk-voltage generating unit to control the gate of the second transistor. When a high voltage input signal is input via the pad, the bulk-voltage generating unit will provide the pad voltage as the gate bias voltage of the second transistor so as to make the second transistor conduct and form a voltage drop. As a result, the reliability of the gate oxide layer of the third transistor is increased and the third transistor is prevented from having the hot-carrier degradation problem. At this time, the bulk voltage also controls the bulk bias voltage of the first transistor to prevent the PN junction diode inside the first transistor from forming a leakage current path.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional I/O buffer.

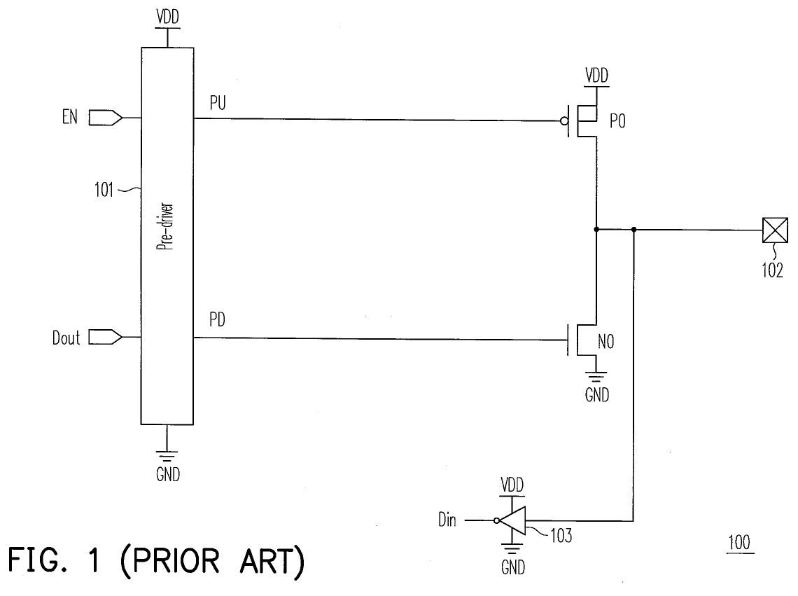

FIG. 2 is a circuit diagram of another conventional I/O buffer.

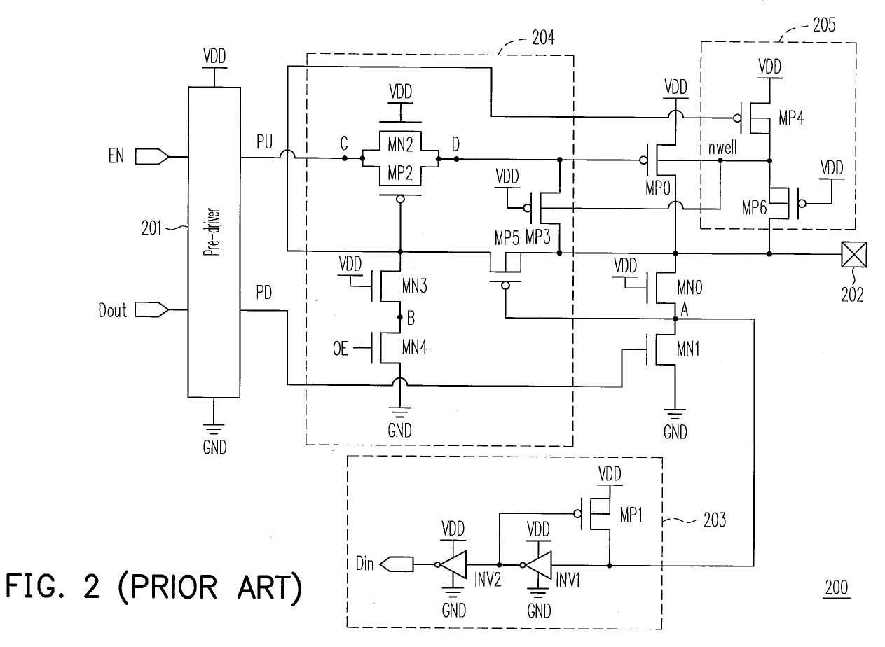

FIG. 3 is a circuit diagram of yet another conventional I/O buffer.

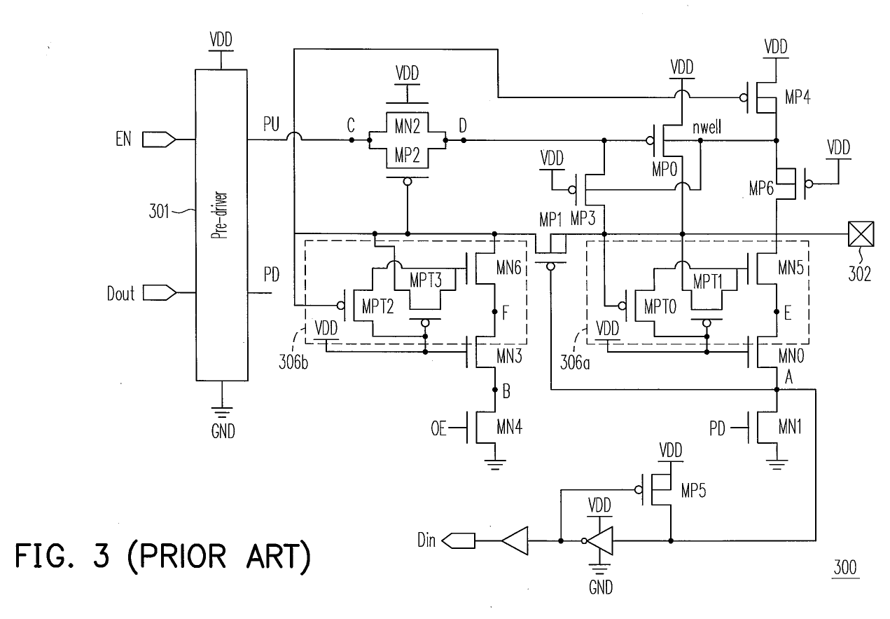

FIG. 4 is a diagram of an Mixed-voltage input and output (I/O) buffer according to an embodiment of the present invention.

FIG. 5 is a table listing the bulk voltages provided by a bulk-voltage generating unit according to an embodiment of the present invention.

FIG. 6 is a circuit diagram of an Mixed-voltage I/O buffer according to an embodiment of the present invention.

FIG. 7 is a circuit diagram of an Mixed-voltage I/O buffer according to an embodiment of the present invention.

FIG. 8 is a circuit diagram of an Mixed-voltage I/O buffer according to an embodiment of the present invention.

FIG. 9 is a circuit diagram of an Mixed-voltage I/O buffer according to an embodiment of the present invention.

FIG. 10 is a circuit diagram of an Mixed-voltage I/O buffer according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

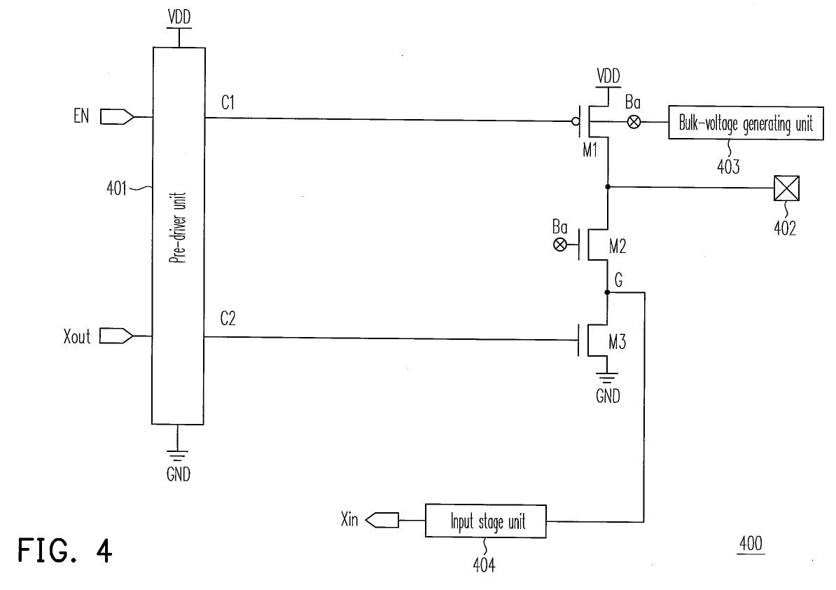

FIG. 4 is a diagram of an Mixed-voltage input and output buffer according to an embodiment of the present invention. As shown in FIG. 4, the Mixed-voltage input and output (I/O) buffer 400 includes a pre-driver unit 401, a bulk-voltage generating unit 403, an input stage unit 404 and transistors M1˜M3. The transistor M1 is a P-type transistor and the transistors M2˜M3 are N-type transistors. The pre-driver unit 401 outputs a first signal C1 and a second signal C2. The bulk-voltage generating unit 403 determines whether a first voltage (a system voltage VDD) or a pad voltage is connected to the output to be used as a bulk voltage Ba according to the voltage level of the pad 402.

A gate of the transistor M1 receives the first signal C1, and a bulk, a first source/drain and a second source/drain are respectively coupled to the bulk voltage Ba, the first voltage and the pad 402. A gate, a first source/drain and a second source/drain of the transistor M2 are respectively coupled to the bulk voltage Ba, the second source/drain of the transistor M1 and a first source/drain of the transistor M3. A gate of the transistor M3 receives the second signal C2, and a second source/drain of the transistor M3 is coupled to the second voltage (a ground voltage GND here). The input stage unit 404 is coupled to the first source/drain of the transistor M3 for receiving an input signal from the pad 402 and transmitting to the interior of an integrated circuit from a node Xin.

The operating mode of the Mixed-voltage I/O buffer 400 of the present embodiment is controlled by an enable signal EN, and the operating mode includes an input mode (for receiving an input signal) and an output mode (for transmitting an output signal). When the Mixed-voltage I/O buffer 400 is in the output mode, the enable signal EN is at a logic high level (for example: VDD), and the first signal C1 and the second signal C2 change according to the voltage level of an output signal Xout.

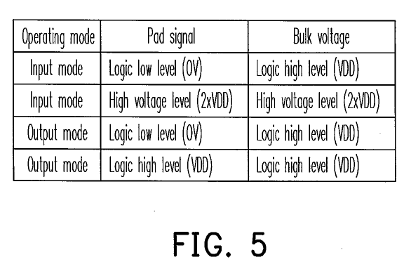

FIG. 5 is a table listing the bulk voltages provided by the bulk-voltage generating unit 403 according to an embodiment of the present invention. As shown in FIG. 5, if a logic high (for example: VDD) output signal is transmitted, then the first signal C1 and the second signal C2 are logic low level (for example: 0V) so as to make the transistor M2 conductive while the transistor M3 non-conductive. At this time, the bulk-voltage generating unit 403 provides a first voltage (e.g. a system voltage VDD) to be used as the bulk voltage Ba and transmits this bulk voltage Ba to the bulk of the transistor M1 so as to prevent the transistor M1 from increasing the turn-on voltage of its gate due to body effect. Therefore, the output signal having the system voltage VDD is transmitted to the pad 402 through the conductive transistor M1.

As shown in FIG. 5, if a logic low (for example: 0V) output signal is transmitted, then the first signal C1 and the second signal C2 are at a logic high level (for example: VDD) so as to make the transistor M1 non-conductive while the transistor M3 conductive. At this time, the bulk-voltage generating unit 403 provides a first voltage to be used as the bulk voltage Ba and transmits this bulk voltage Ba to the gate of the transistor M2 so as to make the transistor M2 conductive. Therefore, the output signal having a ground voltage GND is transmitted to the pad 402 through the conductive transistors M2˜M3.

When the Mixed-voltage I/O buffer 400 is in an input mode, the enable signal EN is at a logic low level (for example: 0V), and the first signal C1 and the second signal C2 are respectively at a high logic level (for example: the system voltage VDD) and a logic low level (for example: 0V) so as to make both transistors M1 and M3 non-conductive. As shown in FIG. 5, if a logic low (for example: 0V) input signal is input via the pad 402, the bulk-voltage generating unit 403 provides a first voltage to be used as the bulk voltage Ba and transmits the bulk voltage Ba to the gate of the transistor M2 so as to make the transistor M2 conductive. Therefore, the input signal is transmitted to the output stage unit 404 through the conductive transistor M2.

As shown in FIG. 5, if a high voltage (for example: two times the system voltage 2×VDD) input signal is input via the pad 402, the bulk-voltage generating unit 403 provides the pad voltage to be used as the bulk voltage Ba and transmits the bulk voltage Ba to the bulk of the transistor M1 and the gate of the transistor M2. Therefore, the PN junction diode inside the transistor M1 will not be disposed in a forward bias condition so as to prevent/eliminate a leakage current path. Furthermore, the first source/drain voltage (node A) of the transistor M3 will also be limited to about 2×VDD−ΔV so as to increase the reliability of the gate oxide layers of the transistor M3 and the transistors inside the input stage unit 404.

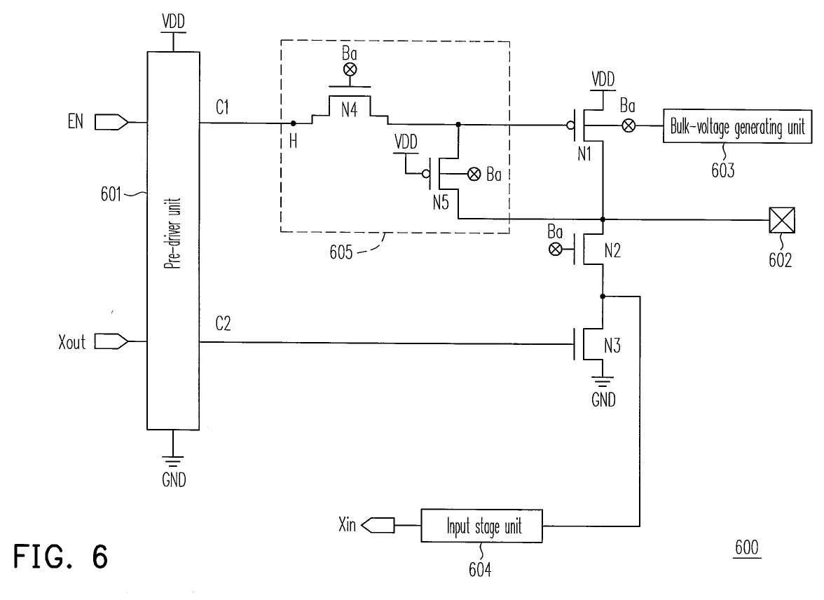

FIG. 6 is a circuit diagram of an Mixed-voltage I/O buffer according to an embodiment of the present invention. As shown in FIGS. 4 and 6, the main difference between the Mixed-voltage I/O buffer 400 in FIG. 4 and the Mixed-voltage I/O buffer 600 in FIG. 6 is that the Mixed-voltage I/O buffer 600 includes an additional gate-tracking unit 605. The gate-tracking unit 605 is coupled between a gate of a transistor N1 and a pre-driver unit 601 for controlling the gate voltage of the transistor N1.

The gate-tracking unit 605 includes transistors N4˜N5. The transistor N4 is an N-type transistor and the transistor N5 is a P-type transistor. A gate, a first source/drain and a second source/drain of the transistor N4 are respectively coupled to the bulk voltage Ba, the pre-driver unit 601 and the gate of the transistor N1. A gate, a bulk, a first source/drain and a second source/drain of the transistor N5 are respectively coupled to the first voltage, the bulk voltage Ba, the gate of the transistor N1 and a second source/drain of the transistor N1.

When a high voltage (for example: 2VDD) input signal is input via the pad 602, the second source/drain voltage of the transistor N5 will be greater than its turn-on voltage so as to make the transistor N5 conductive. Therefore, the gate voltage of the transistor N1 is increased to a voltage level close to the input signal through the conductive transistor N5 so as to prevent the transistor N1 from being conductive and producing a leakage current path. At this time, the bulk-voltage generating unit 603 provides the pad voltage to be used as the bulk voltage Ba and transmits the bulk voltage Ba to the gate of the transistor N4. Therefore, the operation of the transistor N4 is identical to the transistor N2 so that the first source/drain voltage (node H) of the transistor N4 is also limited to about 2×VDD−ΔV.

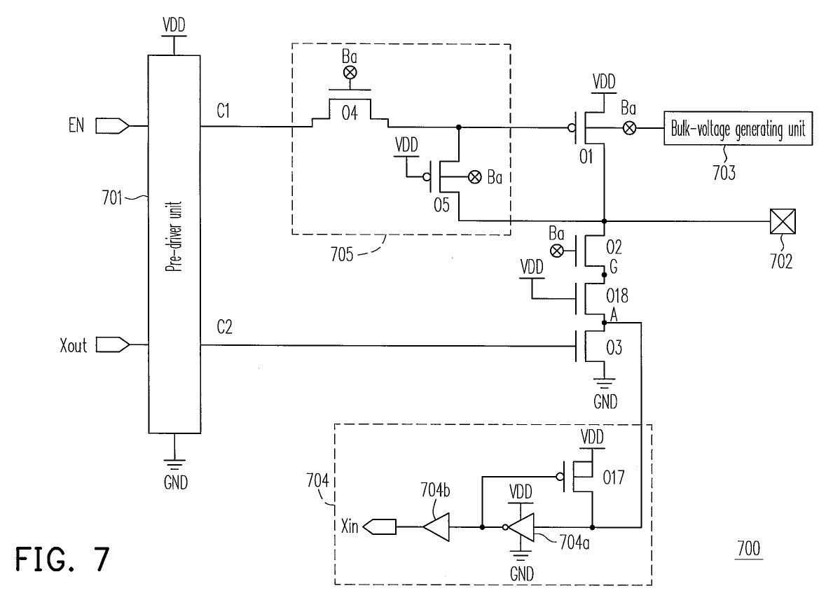

FIG. 7 is a circuit diagram of an Mixed-voltage I/O buffer according to an embodiment of the present invention. As shown in FIGS. 6 and 7, the main difference between the Mixed-voltage I/O buffers is that the Mixed-voltage I/O buffer 700 includes an additional stacked transistor O18. The transistor O18 is an N-type transistor. The input stage unit 704 includes a transistor O17, an inverter 704a and a buffer 704b. A gate, a first source/drain and a second source/drain of the transistor O18 are respectively coupled to a first voltage, a second source/drain of a transistor O2 and a first source/drain of a transistor O3. A gate, a first source/drain and a second source/drain of the transistor O17 are respectively coupled to an output end of the inverter 704a, the first source/drain of the transistor O3 and the first voltage. Furthermore, a bulk and the second source/drain of the transistor O17 are coupled together. An input end of the inverter 704a is coupled to the first source/drain of the transistor O17. An input end and an output end of the buffer 704b are respectively coupled to an output end of the inverter 704a and a node Xin.

When the high voltage (for example: 2×VDD) input signal is input via the pad 702, the conductive transistor O18 can lower the first source/drain voltage (node A) of the transistor O3 so as to prevent the gate oxide layer of the transistor O3 and the transistors inside the inverter 704a from being over-stressed. At this time, the transistor O17 can also effectively keep input end voltage of the inverter 704a toward full swing of VDD so as to avoid the DC leakage current inside the inverter 704a.

When the Mixed-voltage I/O buffer 700 makes a transition from receiving a high voltage (for example: 2×VDD) input signal to transmitting a low logic level (for example: 0V) output signal, the first source/drain voltage (node A) of the transistor O3 drops suddenly following the change of the second signal C2 to a high voltage level (for example: VDD). The voltage level of node G is lowered through the conductive transistor O2 (similar to the description of the embodiment in FIG. 4). Therefore, the voltage between the first source/drain (node G) and the second source/drain (node A) of the stacked transistor O18 will not be large enough to cause the hot-carrier degradation problem.

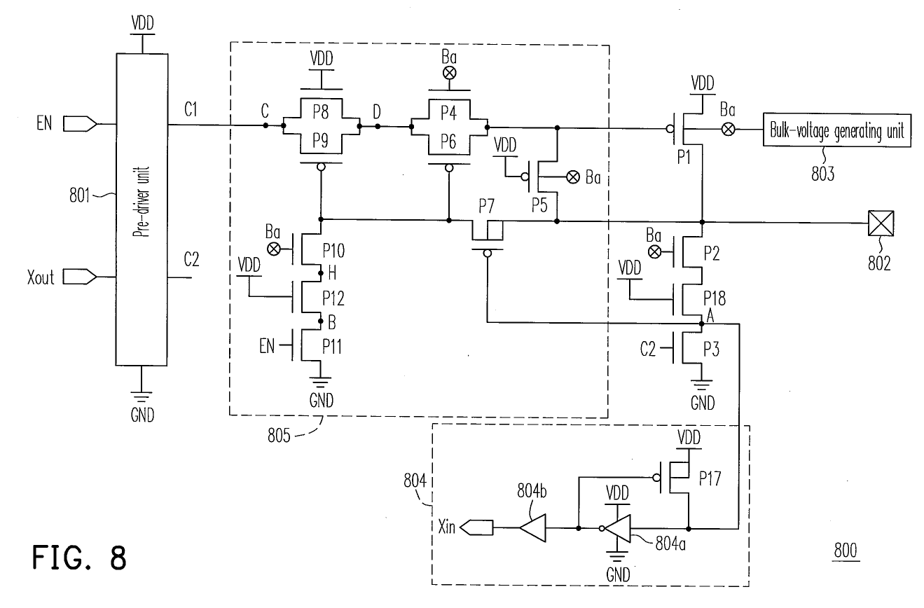

FIG. 8 is a circuit diagram of an Mixed-voltage I/O buffer according to an embodiment of the present invention. As shown in FIGS. 7 and 8, the main difference between the Mixed-voltage I/O buffers is that the gate-tracking unit 805 in FIG. 8 includes additional transistors P6˜P12. The transistors P6˜P7 and P9 are P-type transistors and the transistors P8, P10˜P12 are N-type transistors.

A gate, a first source/drain and a second source/drain of the transistor P6 are respectively coupled to a source/drain of the transistor P7, a first source/drain and a second source/drain of the transistor P4. A gate and a second source/drain of the transistor P7 are respectively coupled to the first source/drain of the transistor P3 and the second source/drain of the transistor P1. Furthermore, a bulk and the second source/drain of the transistor P7 are coupled together. A gate, a first source/drain and a second source/drain of the transistor P8 are respectively coupled to the first voltage (the system voltage VDD here), the pre-driver unit 801 and the first source/drain of the transistor P4. A gate, a first source/drain (i.e. node C) and a second source/drain (i.e. node D) of the transistor P9 are respectively coupled to the first source/drain of the transistor P7 the first and the second source/drain of the transistor P8.

A gate, a first source/drain and a second source/drain of the transistor P10 are respectively coupled to the bulk voltage Ba, the gate of the transistor P6 and a first source/drain of the transistor P12. A gate of the transistor P11 receives the enable signal EN, and a first source/drain and a second source/drain of the transistor P11 are respectively coupled to a second source/drain of the transistor P12 and a second voltage (a ground voltage GND here). A gate of the transistor P12 is coupled to the first voltage (e.g. the system voltage VDD).

When the Mixed-voltage I/O buffer 800 is in an output mode (for transmitting output signal), the enable signal EN is at a high voltage level (for example: VDD). The bulk-voltage generating unit 803 provides a first voltage to be used as a bulk voltage and transmits the bulk voltage to the gates of the transistors P2, P4 and P10. Through the conductive transistors P10˜P11, the gate voltages of the transistors P6 and P9 are pulled down so as to make the transistors P6 and P9 conductive. Therefore, the first signal C1 is transmitted to the gate of the transistor P1 through the conductive transistors P6 and P9 or the conductive transistors P4 and P8.

When a high voltage (for example: 2×VDD) input signal is input via the pad 802, the transistors P6 and P9 are non-conductive. The gate of the transistor P1 is pulled up to close to the voltage level of the input signal through the conductive transistor P5. At this time, the operations of the transistors P4 and P8 are identical to the operations of the transistors P2 and P18, respectively.

When the Mixed-voltage I/O buffer 800 makes a transition from receiving a high voltage (for example: 2×VDD) input signal to transmitting a high logic level (for example: VDD) output signal, the first source/drain voltage (node C) of the transistors P8˜P9 drops suddenly following the change of the first signal C1 to a low voltage level (for example: 0V). At this time, the voltage level of node D is lowered through the transistor P4 (similar to the description of the embodiment in FIG. 4). Therefore, the voltage between the first source/drain (node C) and the second source/drain (node D) of the transistors P8˜P9 will not be large enough to cause the hot-carrier degradation problem.

Furthermore, at the same time as the gate voltage of the transistor P1 is lowered toward a logic low level (for example: 0V), the gate voltages of the transistors P4, P6 and P9 are also lowered toward a low voltage level. Therefore, the voltages between the gates of these four transistors P4, P6, P8 and P9 and the first source/drain on one hand and the second source/drain on the other hand are maintained at a safe value of smaller than the logic high voltage (for example: VDD) so as to protect the gate oxide layers of these transistors.

When the Mixed-voltage I/O buffer 800 makes a transition from receiving a high voltage (for example: 2×VDD) input signal to transmitting a low logic level (for example: 0V) output signal, the first source/drain voltage (node B) of the transistor P11 drops suddenly following the change of the enable signal EN to a logic high level (for example: VDD). The voltage of the first source/drain (node A) of the transistor P3 also drops suddenly following the change of the second signal C2 to a logic high level (for example: VDD) so as to make the transistor P7 conductive.

At this time, the operation of the transistor P10 is identical to the operation of the transistor P2 and the stacked transistor P12 lowers the first source/drain voltage (node B) of the transistor P11 so as to protect the gate oxide layer of the transistor P11. By lowering of the voltage level of node H through the transistor P10, the voltage between the first source/drain (node H) and the second source/drain (node B) of the transistor P12 will not be large enough to cause the hot-carrier degradation problem.

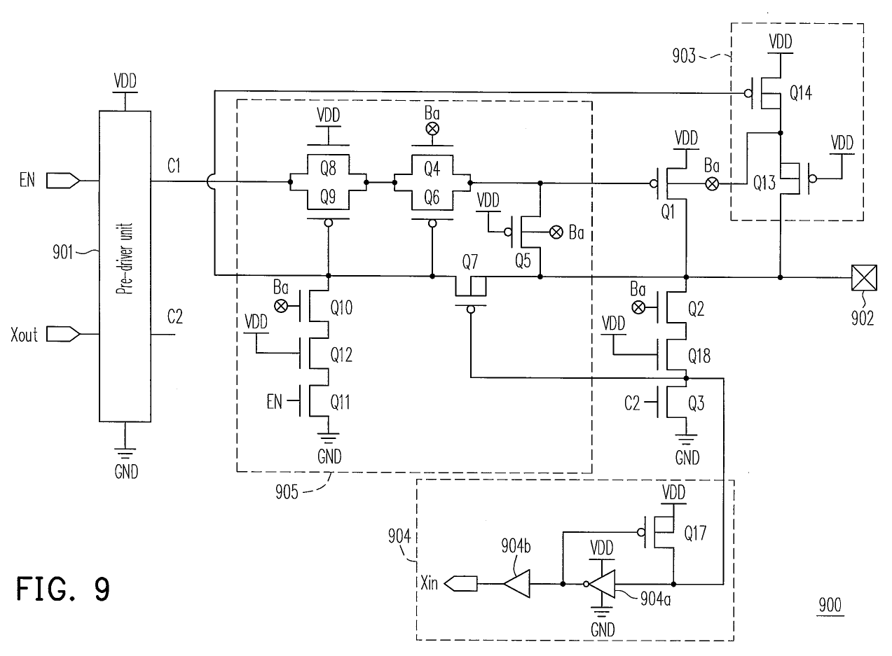

Next, another embodiment is provided to describe the method of implementing the bulk-voltage generating unit. FIG. 9 is a circuit diagram of an Mixed-voltage I/O buffer according to an embodiment of the present invention. As shown in FIGS. 8 and 9, the main difference between the Mixed-voltage I/O buffers is that the bulk-voltage generating unit 903 includes transistors Q13˜Q14. The transistors Q13˜Q14 are P-type transistors. A gate, a first source/drain and a second source/drain of the transistor Q13 are respectively coupled to the first voltage (the system voltage VDD here), the second source/drain of the transistor Q1 and the bulk of the transistor Q1. Furthermore, a bulk and the second source/drain of the transistor Q13 are coupled together. A gate, a first source/drain and a second source drain of the transistor Q14 are respectively coupled to the gate of the transistor Q6, the first voltage and the second source/drain of the transistor Q13, and a bulk and the second source/drain of the transistor Q14 are coupled together.

When the Mixed-voltage I/O buffer 900 is in an output mode (for transmitting an output signal), the transistor Q14 is conductive. Therefore, the bulk-voltage generating unit 903 provides a first voltage to be used as a bulk voltage Ba. When a high voltage (for example: 2×VDD) input signal is input via the pad 902, the first source/drain voltage of the transistor Q13 is greater than the turn-on voltage and makes the transistor Q13 conductive. Therefore, the bulk-voltage generating unit 903 provides the pad voltage to be used as the bulk voltage Ba.

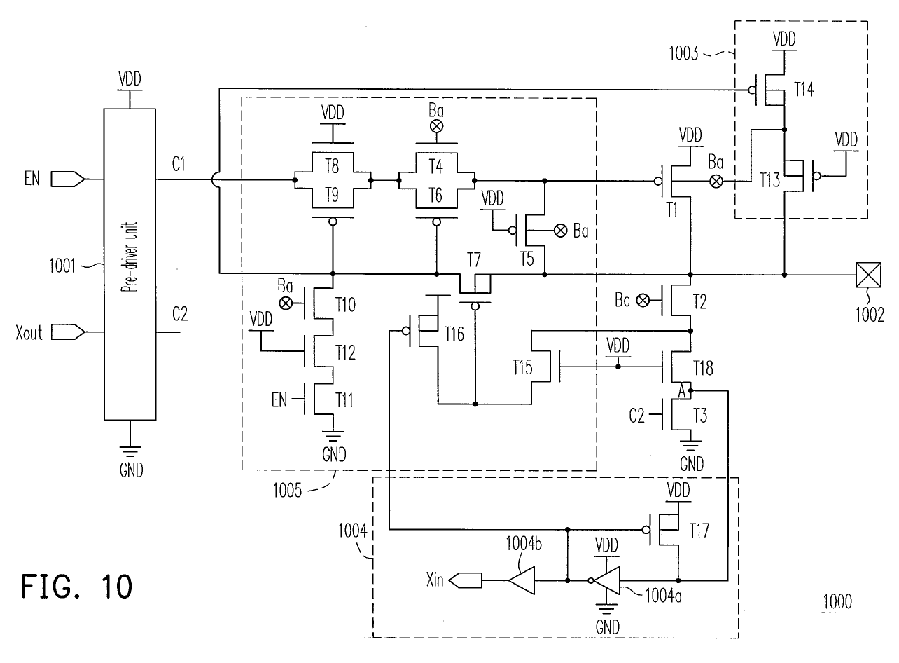

FIG. 10 is a circuit diagram of an Mixed-voltage I/O buffer according to an embodiment of the present invention. As shown in FIGS. 9 and 10, the main difference between the Mixed-voltage I/O buffers is that the Mixed-voltage I/O buffer 1000 includes additional transistors T15˜T16. The transistor T15 is an N-type transistor and the transistor T16 is a P-type transistor. A gate, a first source/drain and a second source/drain of the transistor T15 are respectively coupled to the first voltage (a system voltage VDD here), the second source/drain of the transistor T2 and the gate of the transistor T7. A gate, a first source/drain and a second source/drain of the transistor T16 are respectively coupled to the gate of the transistor T17, the gate of the transistor T7 and the first voltage, and a bulk and the second source/drain of the transistor T17 are coupled together.

The transistors T15˜T16 are used for increasing the reliability of the gate oxide layer of the transistor T7. The operations of the transistors T15 and T16 are respectively identical to the operations of the transistors T18 and T17. When the Mixed-voltage I/O buffer 1000 is in the output mode, the gate voltage of the transistor T7 is maintained at a high logic level (for example: VDD). When the Mixed-voltage I/O buffer 1000 is in the output mode, the gate voltage of the transistor T7 is pulled down to a logic low level (for example: 0V) or a logic high level (for example: VDD). In other words, the gate voltage of the transistor T7 is identical to the first source/drain voltage (node A) of the transistor T3.

With the foregoing arrangement, the gate of the transistor Q7 being connected to a ground voltage GND due to the conductive transistor Q3 as shown in FIG. 9 can be avoided. In other words, the gate voltage of the transistor T7 in the embodiment of FIG. 10 is effectively controlled so as to increase the reliability of the gate oxide layer of the transistor T7.

According to the foregoing embodiments, the bulk-voltage generating unit can determine whether the first voltage or the pad voltage is used as a bulk voltage according to the pad voltage level. When a high voltage input signal is input via the pad, the bulk voltage (the pad voltage) is transmitted to the gate of the transistor so as to make it conductive and for a voltage drop (such as the transistors Q2, Q4 and Q10 in the embodiment of FIG. 9). Therefore, the present embodiment can increase the reliability of the gate oxide layer of the stacked transistors (such as the transistors Q3 and Q11 in the embodiment of FIG. 9). Furthermore, when the Mixed-voltage I/O buffer is in a transient state, hot-carrier degradation of the stacked transistors (such as the transistors Q8, Q9, Q12 and Q18 in the embodiment of FIG. 9) can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An Mixed-voltage input and output (I/O) buffer, coupled to a pad, comprising:
a pre-driver unit for outputting a first signal and a second signal;
a bulk-voltage generating unit for determining whether a first voltage or a pad voltage is connected to an output to be used as a bulk voltage according to the pad voltage level;
a first transistor having a gate for receiving the first signal, a first source/drain coupled to the first voltage, a second source/drain coupled to the pad, and a bulk coupled to the bulk voltage;
a second transistor having a gate for receiving the bulk voltage, and a first source/drain coupled to the second source/drain of the first transistor;
a third transistor having a gate for receiving the second signal, a first source/drain coupled to the second source/drain of the second transistor, and a second source/drain coupled to a second voltage; and
an input stage unit, coupled to the first source/drain of the third transistor for receiving an input signal from the pad.

2. The Mixed-voltage I/O buffer according to claim 1, further comprising:
a gate-tracking unit, coupled between the gate of the first transistor and the pre-driver unit, wherein, if the pad voltage is greater than the first signal, then the pad voltage is selected for outputting to the gate of the first transistor, otherwise, the first signal is selected for outputting to the gate of the first transistor.

3. The Mixed-voltage I/O buffer according to claim 2, wherein the gate-tracking unit comprises:
a fourth transistor having a gate coupled to the bulk voltage, a first source/drain coupled to the pre-driver unit, and a second source/drain coupled to the gate of the first transistor; and
a fifth transistor having a gate coupled to the first voltage, a first source/drain coupled to the gate of the first transistor, a second source/drain coupled to the second source/drain of the first transistor, and a bulk coupled to the bulk voltage.

4. The Mixed-voltage I/O buffer according to claim 3, wherein the gate-tracking unit further comprises:
a sixth transistor having a first source/drain coupled to the first source/drain of the fourth transistor, a second source/drain and a bulk coupled to the second source/drain of the fourth transistor; and
a seventh transistor having a gate coupled to the first source/drain of the third transistor, a first source/drain coupled to a gate of the sixth transistor, a second source/drain and a bulk coupled to the second source/drain of the first transistor.

5. The Mixed-voltage I/O buffer according to claim 4, wherein the gate-tracking unit further comprises:
an eighth transistor having a gate coupled to the first voltage, a first source/drain coupled to the pre-driver unit, and a second source/drain coupled to the first source/drain of the fourth transistor; and
a ninth transistor having a gate coupled to the first source/drain of the seventh transistor, a first source/drain coupled to the first source/drain of the eighth transistor, and a second source/drain coupled to the second source/drain of the eighth transistor.

6. The Mixed-voltage I/O buffer according to claim 4, wherein the gate-tracking unit further comprises:
a tenth transistor having a gate coupled to the bulk voltage, and a first source/drain coupled to the gate of the sixth transistor; and
an eleventh transistor having a gate for receiving an enable signal, a first source/drain coupled to a second source/drain of the tenth transistor, and a second source/drain coupled to the second voltage.

7. The Mixed-voltage I/O buffer according to claim 6, wherein the gate-tracking unit further comprises:
an twelfth transistor having a gate coupled to the first voltage, a first source/drain coupled to the second source/drain of the tenth transistor, and a second source/drain coupled to the first source/drain of the eleventh transistor.

8. The Mixed-voltage I/O buffer according to claim 4, wherein the bulk-voltage generating unit comprises:
a thirteenth transistor having a gate coupled to the first voltage, a first source/drain coupled to the second source/drain of the eleventh transistor, a second source/drain and a bulk coupled to the bulk of the first transistor for outputting the bulk voltage;
a fourteenth transistor having a gate coupled to the first source/drain of the seventh transistor, a first source/drain coupled to the first voltage, and a second source/drain and a bulk coupled to the second source/drain of the thirteenth transistor.

9. The Mixed-voltage I/O buffer of claim 3, wherein the gate-tracking unit further comprises:
a sixth transistor having a first source/drain coupled to the first source/drain of the fourth transistor, a second source/drain and a bulk coupled to the second source/drain of the fourth transistor;
a seventh transistor having a first source/drain coupled to a gate of the sixth transistor, a second source/drain and a bulk coupled to the second source/drain of the first transistor;
a fifteenth transistor having a gate coupled to the first voltage, a first source/drain coupled to the second source/drain of the second transistor, and a second source/drain coupled to the gate of the seventh transistor; and
a sixteenth transistor having a gate coupled to the input stage unit, a first source/drain coupled to the gate of the seventh transistor, a second source/drain and a bulk coupled to the first voltage.

10. The Mixed-voltage I/O buffer according to claim 9, wherein the input stage unit comprises:
a seventeenth transistor having a gate coupled to the gate of the sixteenth transistor, a first source/drain coupled to the first source/drain of the third transistor, a second source/drain and a bulk coupled to the first voltage;
an inverter having an input end coupled to the first source/drain of the seventeenth transistor, and an output end coupled to the gate of the seventeenth transistor; and
a buffer having an input end coupled to the output end of the inverter.

11. The Mixed-voltage I/O buffer according to claim 1, wherein the input stage unit comprises:
a seventeenth transistor having a first source/drain coupled to the first source/drain of the third transistor, and a second source/drain and a bulk coupled to the first voltage;
an inverter having an input end coupled to the first source/drain of the seventeenth transistor, and an output end coupled to the gate of the seventeenth transistor; and
a buffer having an input end coupled to the output end of the inverter.

12. The Mixed-voltage I/O buffer according to claim 1, further comprising:
an eighteenth transistor having a gate coupled to the first voltage, a first source/drain coupled to the second source/drain of the second transistor, and a second source/drain coupled to the first source/drain of the third transistor.

13. The Mixed-voltage I/O buffer according to claim 1, wherein the pad is an input pad.

14. The Mixed-voltage I/O buffer according to claim 1, wherein the pad is an output pad.
